(19) United States
(12) Patent Application Publication
(10) Pub. No.: US 2009/0075023 A1
(43) Pub. Date: Mar. 19, 2009

(54) METHOD FOR PRODUCING THERMAL BARRIER COATING AND A THERMAL BARRIER COATING

(75) Inventors: Thomas COSACK, Windach (DE); Andreas JAKIMOV, Muenchen (DE)

Correspondence Address: CROWELL & MORING LLP;INTELLECTUAL PROPERTY GROUP, P.O. BOX 14300, WASHINGTON, DC, 20044-4300, US

(73) Assignee: MTU AERO ENGINES GMBH, Munich (DE)

(21) Appl. No.: 12/209,941

(22) Filed: Sep. 12, 2008

(30) Foreign Application Priority Data
Sep. 13, 2007 (DE) 10 2007 043 791.0

(51) Int. Cl. B32B 3/00; C23C 16/40; C23C 14/34

(52) U.S. Cl. 428/119; 427/255.19; 427/585; 204/192.15

(57) ABSTRACT

A method for producing a ceramic thermal barrier coating on a component part for use in compressor and turbine components by a vapor depositing process is disclosed. The method includes: a) provision of a ceramic vapor for depositing on the component part; b) depositing of the ceramic vapor on the component part to form a thermal barrier coating having a columnar structure, the columns being oriented substantially perpendicular to a surface of the component part; and c) varying of at least one method parameter during method step b) in such a way that the resultant thermal barrier coating has columns of alternating decreasing and increasing diameters. A thermal barrier coating is also disclosed. The thermal barrier coating has a ceramic thermal barrier coating having a columnar structure and the columns are oriented substantially perpendicular to a surface of the corresponding part. The columns have alternately decreasing and increasing diameters.

This application claims the priority of German Patent Document No. 10 2007 043 791.0, filed Sep. 13, 2007, the disclosure of which is expressly incorporated by reference herein.

### BACKGROUND AND SUMMARY OF THE INVENTION

The present invention relates to a method for producing a ceramic thermal barrier coating on a component part for use in compressor and turbine components by means of a vapor depositing method as well as a thermal barrier coating for component parts for use in compressor and turbine components, wherein the thermal barrier coating is normally comprised of a ceramic thermal barrier coating having a columnar structure and columns being oriented substantially perpendicular to a surface of the component part. The invention also relates to a component part for use in compressor and turbine components comprised of a metal substrate and a thermal barrier coating applied at least partially to the metal substrate.

Various methods for producing a ceramic thermal barrier coating on component parts are known from the prior art, in particular for use in compressor and turbine components. In this case, a ceramic layer is applied to the component part using either a plasma spray method or by means of a physical vapor depositing method (PVD). Ceramic layers with columnar structures arise through the use of physical vapor depositing methods, in particular also electron beam vaporization (EB-PVD). In this case, the columns have a constant thickness over their lengths. Even the columnar substructure of the column is homogeneous. The advantage of ceramic thermal barrier coatings produced in this manner over the thermal barrier coatings produced by a thermal spray process is that they have an improved resistance to thermal change due to the columnar structure. In addition, the individual columns permit an expansion and contraction of the column structure without stress occurring, which in extreme cases could lead to individual parts of the thermal barrier coating flaking off. Because of the additional application of thermal insulating ceramic layers on the cited component parts, the material temperature of the component part is reduced and strength is thereby maintained. Zirconium oxide with various stabilizers, particularly yttrium oxide, is used as the ceramic material most of the time in this case. Methods for producing ceramic thermal barrier coatings and corresponding thermal barrier coatings for metal component parts for use in compressor and turbine components are known from German Patent Document Nos. DE 601 03 526 T2 and DE 693 18 856 T2 as well as from U.S. Pat. Nos. 4,321,311 A, 4,401,697 A, 4,405,659 A and 5,514,482.

What is disadvantageous in terms of the known methods for producing ceramic thermal barrier coatings as well as the thermal barrier coatings produced from them, however, is that relatively thick columnar structures are generated with the use of physical vapor depositing methods. However, the relatively high density disadvantageously promotes the flow of heat within the ceramic thermal barrier coating.

As a result, the objective of the present invention is providing a generic thermal barrier coating for a component part with a very clearly reduced thermal conductivity.

It is further the objective of the invention to provide a generic method for producing a ceramic thermal barrier coating, in which the resulting thermal barrier coating features a distinct, in particular reduced, thermal conductivity.

Moreover, another objective of the present invention is providing a component part for use in compressor and turbine components comprised of a metal substrate and a thermal barrier coating applied at least partially to the metal substrate, wherein the thermal barrier coating features a very clearly reduced thermal conductivity as compared with known thermal barrier coatings.

An inventive method for producing a ceramic thermal barrier coating on a component part for use in compressor and turbine components comprises a vapor depositing method with the following method steps: a) provision of a ceramic vapor for depositing on the component part; b) depositing of the ceramic vapor on the component part to form a thermal barrier coating having a columnar structure, the columns being oriented substantially perpendicular to a surface of the component part; and c) varying of at least one method parameter during method step b), in such a way that the resultant thermal barrier coating comprises columns, which have different geometries, in particular alternating decreasing and increasing diameters. According to the invention, the ceramic vapor or the ceramic material is comprised of zircon oxide or zirconium oxide and A₂O₃, wherein the A in A₂O₃ is selected from a group comprising Er, Nd, Yb, Eu, Dy, Gd, Sc, La, Al and Pr. It can be provided in a preferred development that the ceramic vapor or the ceramic material be comprised of a zircon oxide or zirconium oxide and a mixture of at least two oxides from a group of oxides, which group is comprised of Er₂O₃, Nd₂O₃, Yb₂O₃, Eu₂O₃, Dy₂O₃, Gd₂O₃, Sc₂O₃, La₂O₃, Al₂O₃ and Pr₂O₃ or which group is comprised of oxides of Er, oxides of Nd, oxides of Yb, oxides of Eu, oxides of Dy, oxides of Gd, oxides of Sc, oxides of Al, oxides of La and oxides of Pr.

The vapor depositing method is particularly a physical vapor depositing method, such as, for example, an electron beam vapor depositing method. However, using a cathode sputtering method or an arc welding vaporization method as well as CVD methods is also conceivable. The use of a vapor depositing method guarantees that the developing thermal barrier coating has a columnar structure and thus the already known advantages of such structured ceramic thermal barrier coatings are retained. According to the invention, the emerging columns have different geometries, in particular alternating decreasing and increasing diameters. Because of the alternating decreasing and increasing diameters, pores develop between the individual columns in the course of the layer development of the thermal barrier coating and these pores contribute to clearly reducing the heat flow and thus the thermal conductivity of the emerging thermal barrier coating. The feature of the decreasing and increasing diameters should also be understood in particular in this case such that adjacent columns do not touch at least in sections over their lengths and do not run parallel. The same applies to any substructure that may develop. In addition, the smaller diameters of the individual columns advantageously massively inhibit the flow of heat so that this also results in a substantial reduction in the thermal conductivity of the emerging thermal barrier coating.

In other advantageous embodiments of the inventive method, the method is carried out in a coating chamber, in particular a vacuum chamber. In this case, the to-be-coated component part is introduced into the coating chamber and the ceramic thermal barrier coating is deposited on it.

The component part is normally warmed or heated at least on the to-be-coated surface of the component part.

In addition, it is possible for oxygen and inert gas to be fed in during method step b) and the varying of at least one method parameter during method step c) to be comprised of varying the partial pressure of oxygen and/or of the inert gas during coating or in the coating chamber. In the process, the partial pressures and even the overall pressure can be regulated via the gas flows or the pumping capacity. However, it is also possible for the to-be-coated component part to be moved during method step b) and the varying of at least one method parameter during method step c) to be comprised of varying the type of component movement and/or component speed during coating. In this case, the component part can be rotated in particular so that the varying of at least one method parameter during method step c) is comprised of varying the rotational speed during coating. In addition, it is possible for the varying of at least one method parameter during method step c) to be comprised of varying the deposition rate of the ceramic vapor on the component part during coating. Finally, it is possible to vary at least one method parameter during method step c) by varying the pressure during coating in the coating chamber. The cited measures result in the inventive layer structure of the ceramic thermal barrier coating, wherein the emerging columns have different geometries, in particular alternating decreasing and increasing diameters along their longitudinal extensions.

Normally, the thermal barrier coating is deposited in a thickness of between 1 and 400 μm, however, other layer thicknesses are also conceivable.

In a further advantageous embodiment of the inventive method a bonding layer is formed at least partially between the to-be-coated component part surface and the thermal barrier coating. The bonding layer in this case can be comprised of MCrAlY alitized/Al-enriched surfaces, or Pt/Al. In this case, the bonding layer can be applied by means of known thermal spray methods, galvanic methods, diffusion treatment methods or even by means of physical vapor depositing methods. In addition, in another embodiment of the inventive method it is possible for an intermediate layer of aluminum oxide to be formed at least partially between the to-be-coated component part surface and the bonding layer.

An inventive thermal barrier coating is comprised of ceramic material and has a columnar structure or grain structure, wherein the columns are oriented substantially perpendicular to a surface of the component part. According to the invention, the columns have different geometries, in particular alternating decreasing and increasing diameters along their longitudinal extensions. The ceramic material of the thermal barrier coating is comprised of zircon oxide or zirconium oxide and A₂O₃, wherein the A in A₂O₃ is selected from a group comprising Er, Nd, Yb, Eu, Dy, Gd, Sc, La, Al and Pr. According to a preferred development, it can be provided that the ceramic material of the thermal barrier coating be comprised of a zircon oxide or zirconium oxide and a mixture of at least two oxides from a group of oxides, which group is comprised of Er₂O₃, Nd₂O₃, Yb₂O₃, Eu₂O₃, Dy₂O₃, Gd₂O₃, Sc₂O₃, Al₂O₃, La₂O₃ and Pr₂O₃ or which group is comprised of oxides of Er, oxides of Nd, oxides of Yb, oxides of Eu, oxides of Dy, oxides of Gd, oxides of Sc, oxides of Al, oxides of La and oxides of Pr.

The grain boundaries of the individual columns can touch at least partially, advantageously forming pore spaces between the individual columns. The preferred development of the inventive structure or formation of the individual columns results in a clear reduction in the thermal conductivity of the thermal barrier coating since the small diameters of the individual columns massively inhibit the flow of heat. In addition, the pores formed within the thermal barrier coating significantly reduce the flow of heat.

The thermal barrier coating normally features a thickness of between 1 and 400 μm, wherein other thicknesses are also conceivable.

An inventive component part for use in compressor and turbine components is comprised of a metal substrate and an inventive thermal barrier coating applied at least partially to the metal substrate, as described in the foregoing. A correspondingly coated component part has a clearly lower wear rate with a correspondingly higher service life due to the clear reduction of the thermal conductivity of the thermal barrier coating in accordance with the present invention.

In other advantageous embodiments of the inventive component part, a bonding layer, in particular made of MCrAlY and Pt/Al, can be formed at least partially between the substrate and the thermal barrier coating. It is also possible for an intermediate layer made of aluminum oxide to be formed at least partially between the substrate and the bonding layer. The inventive component part is an element of a gas turbine engine in particular.

Additional advantages, characteristics and details are disclosed in the following description of an exemplary embodiment that is depicted graphically.

### BRIEF DESCRIPTION OF THE DRAWINGS

FIG. 1 is a schematic sectional representation of a component part with a thermal barrier coating in accordance with the prior art;

FIG. 2 is a exemplary, schematic sectional representation of a component part with an inventive thermal barrier coating;

FIG. 3 is another exemplary, schematic sectional representation of a component part with an inventive thermal barrier coating; and

FIG. 4 is a further exemplary, schematic sectional representation of a component part with an inventive thermal barrier coating.

### DETAILED DESCRIPTION OF THE DRAWINGS

FIG. 1 shows a schematic sectional representation of a component part or a metallic substrate 18 with a thermal barrier coating 22 arranged on it. A bonding layer 20, in particular made of MCrAlY or Pt/Al, is formed between the thermal barrier coating 22 and the surface 16 of the component part. One can see that the thermal barrier coating 22 has a columnar structure, wherein the individual columns 24 are oriented substantially perpendicular to the surface 16 of the component part. The grain boundaries 26, 28 of respectively different columns 24 touch in the process over the longitudinal extension of the column 24. This results in a relatively thick columnar structure that promotes the flow of heat within the ceramic thermal barrier coating 22.

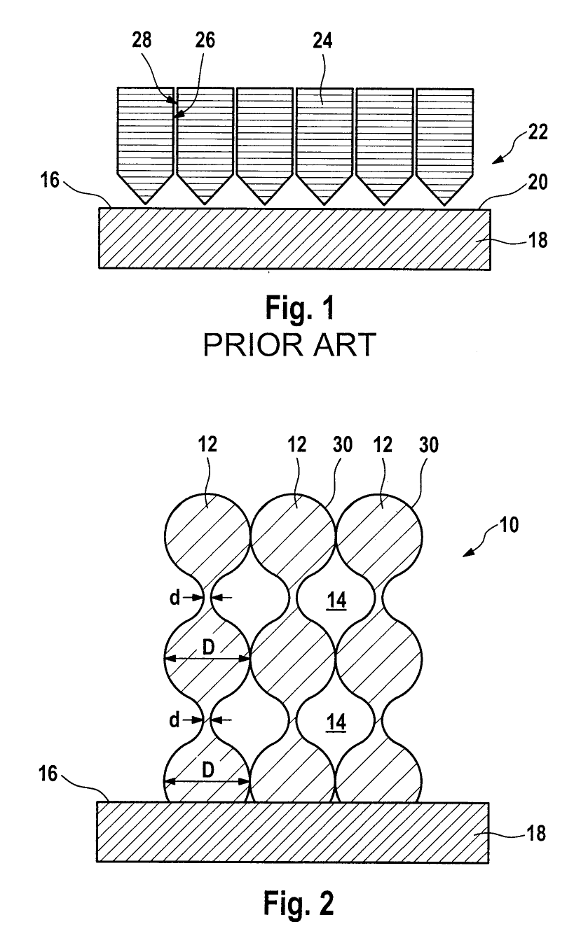

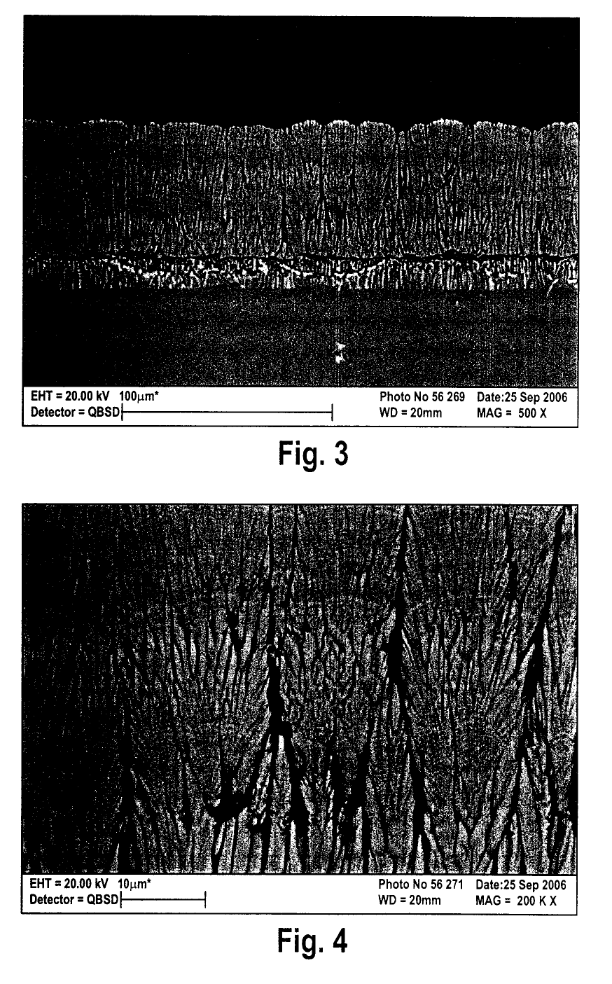

FIGS. 2 through 4 each show a schematic sectional representation of a ceramic thermal barrier coating 10, which was applied to component part surface 16 of the component part 18 or was deposited there; it must be noted that no reference numbers have been entered in FIGS. 3 and 4, however, they are applicable there in a corresponding manner.

One can see that the thermal barrier coating 10 is again comprised of columns 12, which are oriented substantially perpendicular to the surface 16 of the component part. In contrast to the known column structure depicted in FIG. 1, the columns 12 shown in FIG. 2 have alternating decreasing and increasing diameters d, D along their longitudinal extensions. One can see that the grain boundaries 30 of the individual columns touch at least partially, but pores 14 are formed between the individual columns 12. Because of the small diameters d in the individual columns, the heat flow within the thermal barrier coating 10 is massively inhibited. In addition, the density of the thermal barrier coating 10 is clearly reduced due to the pores 14 so that the flow of heat within the thermal barrier coating 10 is also hereby clearly reduced.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A method for producing a ceramic thermal barrier coating on a component part for use in compressor and turbine components, comprising the steps of:
a) providing of a ceramic vapor for depositing on the component part, wherein the ceramic vapor is comprised of zircon oxide or zirconium oxide and A₂O₃, wherein the A in A₂O₃ is selected from a group comprising Er, Nd, Yb, Eu, Dy, Gd, Sc, La, Al and Pr;
b) depositing of the ceramic vapor on the component part to form a thermal barrier coating having a columnar structure, wherein columns of the columnar structure are oriented substantially perpendicular to a surface of the component part; and
c) varying of at least one method parameter during method step b) in such a way that the columns have alternating decreasing and increasing diameters.

2. The method according to claim 1, wherein the depositing step is a physical vapor depositing method (PVD).

3. The method according to claim 2, wherein the physical vapor depositing method (PVD) is an electron beam vapor depositing method (EB-PVD), a cathode sputtering method, or an arc welding vaporization method.

4. The method according to claim 1, wherein the method is carried out in a vacuum chamber.

5. The method according to claim 1, wherein oxygen and inert gas are fed in during method step b) and the step of varying of at least one method parameter in method step c) is comprised of varying a partial pressure of the oxygen and/or of the inert gas during coating or in a coating chamber.

6. The method according to claim 1, wherein the component part is moved during method step b) and the step of varying of at least one method parameter in method step c) is comprised of varying a type of component movement and/or a component speed during coating.

7. The method according to claim 6, wherein the component part rotates and the step of varying of at least one method parameter in method step c) is comprised of varying a rotational speed during coating.

8. The method according to claim 1, wherein the step of varying of at least one method parameter in method step c) is comprised of varying a deposition rate of the ceramic vapor on the component part during coating.

9. The method according to claim 1, wherein the step of varying of at least one method parameter in method step c) is comprised of varying a pressure during coating or in the coating chamber.

10. The method according to claim 1, wherein the ceramic vapor is comprised of zircon oxide or zirconium oxide and a mixture of at least two oxides from a group of oxides, which group of oxides is comprised of oxides of Er, oxides of Nd, oxides of Yb, oxides of Eu, oxides of Dy, oxides of Gd, oxides of Sc, oxides of Al, oxides of La and oxides of Pr.

11. The method according to claim 1, wherein the thermal barrier coating is deposited in a thickness of between 1 and 500 μm.

12. The method according to claim 1, wherein a bonding layer is formed at least partially between the surface of the component part and the thermal barrier coating.

13. The method according to claim 12, wherein the bonding layer features MCrAlY and/or Pt/Al or is comprised thereof and/or is Al-enriched or alitized.

14. The method according to claim 12, wherein an intermediate layer of aluminum oxide is formed at least partially between the surface of the component part and the bonding layer.

15. The method according to claim 1, wherein the ceramic vapor further includes at least one additive from a group of additives, which group is comprised of HfO₂, MgO, MnO and ClO₂ as well as mixtures or two or more of the aforementioned additives.

16. A thermal barrier coating for a component part for use in compressor and turbine components, comprising a ceramic thermal barrier coating having a columnar structure with columns, wherein the columns are oriented substantially perpendicular to a surface of the component part, wherein the columns have alternating decreasing and increasing diameters, and wherein a ceramic material of the ceramic thermal barrier coating is comprised of A₂O₃, wherein the A in A₂O₃ is selected from a group comprising Er, Nd, Yb, Eu, Dy, Gd and Pr.

17. The thermal barrier coating according to claim 16, wherein grain boundaries of the columns touch at least partially.

18. The thermal barrier coating according to claim 16, wherein pore spaces are formed between the columns.

19. The thermal barrier coating according to claim 16, wherein the ceramic material of the ceramic thermal barrier coating is comprised of zircon oxide and a mixture of at least two oxides from a group of oxides, which group is comprised of oxides of Er, oxides of Nd, oxides of Yb, oxides of Eu, oxides of Dy, oxides of Gd, oxides of Sc, oxides of Al, oxides of La and oxides of Pr.

20. The thermal barrier coating according to claim 16, wherein the ceramic thermal barrier coating has a thickness of between 1 and 500 μm.

21. The thermal barrier coating according to claim 16, wherein the ceramic material of the ceramic thermal barrier coating further includes at least one additive from a group of additives, which group is comprised of HfO₂, MgO, MnO and ClO₂ as well as mixtures or two or more of the aforementioned additives.

22. A component part for use in compressor and turbine components, comprising a metal substrate and a thermal barrier coating applied at least partially to the metal substrate according to claim 16.

23. The component part according to claim 22, wherein a bonding layer is formed at least partially between the metal substrate and the thermal barrier coating.

24. The component part according to claim 23, wherein the bonding layer is comprised of MCrAlY and/or is Al-enriched or alitized.

25. The component part according to claim 23, wherein an intermediate layer of aluminum oxide is formed at least partially between the metal substrate and the bonding layer.

26. The component part according to claim 22, wherein the component part is an element of a gas turbine engine.
